(19) United States
(12) Patent Application Publication
(10) Pub. No.: US 2026/0123000 A1
(43) Pub. Date: Apr. 30, 2026

(54) Passivation and High Temperature Oxidation of Iridium Oxide Schottky Contacts for III-Nitride Devices

(71) Applicant: The Board of Trustees of the Leland Stanford Junior University, Stanford, CA (US)

(72) Inventors: Savannah Eisner, Hoboken, NJ (US); Debbie G. Senesky, Oakland, CA (US)

(21) Appl. No.: 18/865,808

(22) PCT Filed: Jun. 9, 2023
(86) PCT No.: PCT/US2023/024989

§ 371 Date: Nov. 14, 2024

Related U.S. Application Data
(60) Provisional application No. 63/351,122, filed on Jun. 10, 2022.

(51) Int. Cl. H01L 21/285; H10D 30/01; H10D 30/47; H10D 62/824; H10D 64/60

(52) U.S. Cl. CPC H10D 64/0124; H10D 30/015; H10D 30/475; H10D 62/824; H10D 64/602

(57) ABSTRACT

We provide a fabrication process for III-nitride devices. An iridium structure is deposited and then oxidized at high temperature (700° C. or more) to form an iridium oxide Schottky contact to a III-nitride. This IrOₓ contact is then protected with a passivation structure. Such contacts have various device applications, such as forming Schottky diodes and acting as a gate in a transistor or 2D electron gas structure.

### FIELD OF THE INVENTION

This invention relates to fabrication of III-Nitride devices having improved high temperature performance and survivability.

### BACKGROUND

Typically, microelectronics are designed to perform reliably at temperatures of 70° C. for commercial grade electronics, 85° C. for industrial grade, and 125° C. for military grade. Above these temperatures, semiconductor devices often fail to meet critical parameters and degradation can cause permanent failure.

Microelectronics capable of operating reliably at high temperature are necessary to provide sensing, readout, and telecommunications for applications in the space, aerospace, defense, automotive, and oil and gas sectors. Examples of such applications include down-hole oil and gas drilling, under-the-hood automotive, and aircraft engine-control systems, hypersonics, as well as leak detection in carbon, capture, and storage (CCS) wellbores. AIN-based high electron mobility transistors (HEMTs) that leverage the two-dimensional electron gas (2 DEG) have shown promise for operating at high temperature. However, the reliability is often not limited by the heterostructure itself, but by the degradation of the accompanying metallization and passivation layers. Accordingly, it would be an advance in the art to provide improved high temperature III-Nitride devices.

### SUMMARY

Here, we present a Schottky gate material that can enable reliable high-temperature operation of these devices; it has not demonstrated well-known degradation mechanisms such as metal diffusion or electromigration during electrical characterization at high temperatures up to 600 degrees Celsius.

This work provides a microfabrication process on AIN-based 2 DEG devices. In our experiments, we electron beam evaporated 15 nm of Iridium to form the gate electrode on InAlN/GaN high electron mobility transistors (HEMTs). Then, we intentionally oxidized the Ir gate by placing it into a rapid thermal anneal furnace and flowing oxygen at 800° C. for 1 min. The gate is now considered to be iridium oxide (IrOₓ). A passivation layer on top is also included. A passivation layer of an inert material, such as aluminum oxide, can provide protection from the environmental conditions of the operating ambient. For example, a passivation layer can protect the iridium oxide gate from further oxidation when operating the device at high temperatures in air.

Transistors are most commonly fabricated in the linear format with parallel source, gate, and drain terminals. In preferred embodiments, the IrOₓ-gated HEMTs could have a circular geometry, with concentric source, gate, and drain terminals. The circular geometry is advantageous from a reliability perspective because the gate only overlaps the mesa region edge once or not at all; in the linear format, the gate overlaps the mesa region edge twice. It is preferable to reduce the surface area of the gate and mesa edge overlap region because this region is a known current leakage path, and can also allow the gate material to more easily diffuse into the device conducting channel from the side contact.

Exemplary applications include:
1) Supercritical CO₂ well leak detection. The oxidized iridium gates can provide stable electrical performance after exposure to supercritical CO₂ ambient, indicating their chemical inertness in this atmosphere.
2) Uncooled downhole sensor readout for the oil and gas industry. Depths >15,000 feet often see temperatures in excess of 200° C. for extended periods.
3) Long-lived mission to the surface of Venus (surface temperature 465° C.).
4) Industrial under-the-hood engine applications
5) Gas turbines
6) Hypersonic structures. Monitoring dynamic pressure changes from supersonic air flow requires signal-conditioning electronics capable of operation at 800° C.

Significant advantages are provided. Competing technologies could include silicon-on-insulator (SOI) or silicon carbide (SiC) based devices, which also offer some advantages for high-temperature operation. Intentionally oxidized iridium (IrOₓ) gates have previously been demonstrated on AlGaN/GaN HEMTs (without passivation); however, InAlN/GaN HEMTs do not rely on piezoelectric polarization to induce high carrier density in the 2 DEG. This means that they are free from deleterious strain relaxation effects at high temperature that have been demonstrated to lower the 2 DEG density and adversely affect device performance.

Advantages over silicon carbide: InAlN/GaN and other aluminum-nitride based devices can offer higher electron mobilities so they are better for high frequency, high temperature applications.

Advantages of InAlN/GaN over AlGaN: AlGaN 2 DEG density is dependent on strain in the system; strain relaxation has been reported at high temperature and this reduces the 2 DEG density. But AlN barrier layers with 17-18% In incorporation (InAlN) are lattice-matched, so there is no strain in the system. This is better for high temperature because it will not suffer from strain relaxation.

### BRIEF DESCRIPTION OF THE DRAWINGS

FIG. 1 shows an exemplary device fabricated according to an embodiment of the invention.

FIGS. 2A-F shows a fabrication sequence according to an exemplary embodiment of the invention.

FIGS. 3A-C show a more detailed view of the iridium oxidation step of FIG. 2D.

FIGS. 4A-C are images showing several fabricated devices.

FIG. 5 is an image of a device used for Schottky contact characterization.

FIGS. 6A-C show temperature cycling results that demonstrate the importance of passivation.

FIGS. 7A-D are band diagrams showing various current conduction mechanisms that were considered in experimental device characterization.

FIG. 8 shows exemplary J-V data at several temperatures for a Schottky contact fabricated according to an embodiment of the invention.

FIG. 9 shows exemplary device characterization results at several temperatures.

### DETAILED DESCRIPTION

### A) General Principles

In this work, we describe an experimental demonstration of an approach for making Schottky contacts to III-nitride devices that has shown good performance and survivability in extreme high temperature operation. Making contacts is an area of semiconductor technology that tends to be unpredictable, so it is difficult to extrapolate from reported results in the literature. In particular, III-Nitride material systems are relatively less explored than more established material systems like silicon, so suitable materials and processes for making contacts (both ohmic and Schottky) are not as well known. Operation at extreme temperatures increases these uncertainties. Here a “III-nitride” material is a III-V material with nitrogen being the V species. Examples include InN, GaN, AlN, BN and binary, ternary or quaternary alloys of these.

Accordingly, an exemplary embodiment of the invention is a method of making a Schottky contact in a III-nitride device structure, where the method includes:
i) depositing an iridium structure on a III-nitride device structure;
ii) oxidizing the iridium structure to convert it to an iridium oxide structure at a oxidizing temperature of 700° C. or more (but preferably also less than 1000° C.), thereby forming a Schottky contact; and
iii) depositing a passivation structure on the iridium oxide structure.

The passivation structure can include one or more materials including, but not limited to: aluminum oxide, silicon dioxide, silicon nitride, and silicon oxynitride.

The III-Nitride device structure can be an InAlN structure on a GaN substrate. This is the example considered in the experimental work described below.

The Schottky contact can operate at temperatures up to 500° C. (or more). The iridium oxide structure can be electrically conductive, and thereby able to act as a gate electrode for a device. Thus the III-Nitride device structure can be a gated 2D electron gas device. The III-Nitride device structure can also be a transistor structure, such as a high electron mobility transistor. In this case, the transistor structure preferably has a circular geometry with concentric source, gate and drain terminals.

### B) Exemplary Fabrication Sequences

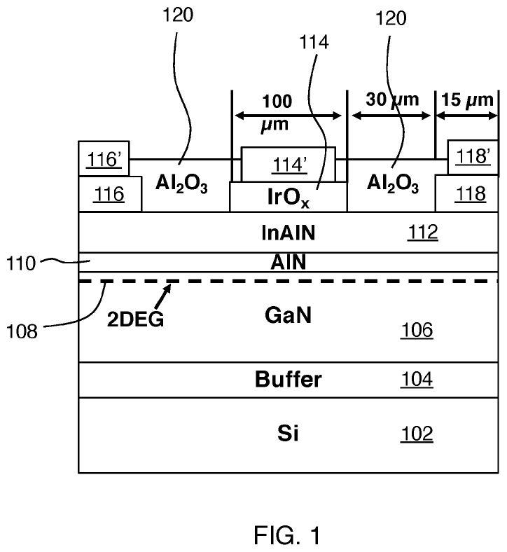

FIG. 1 shows the device structure of the following examples. Here a layer structure having GaN (106) on buffer 104 on a Si substrate (102) includes a 2D electron gas 108 in layer 106 as shown. An AlN layer 110 is disposed on layer 106, and an InAlN layer 112 is disposed on layer 110. This example is a high electron mobility transistor having a source 116, a gate 114, and a drain 118. Contact pads to these terminals are referenced as 116′, 114′, 118′ respectively. A passivation structure 120 (Al₂O₃ in this example) is disposed to cover the gate 114.

Three features of this example are of particular importance: 1) gate 114 is composed of iridium oxide; 2) this iridium oxide gate is formed by a high temperature oxidation process as indicated above and described in further detail below; and 3) this iridium oxide gate is protected with a passivation structure 120.

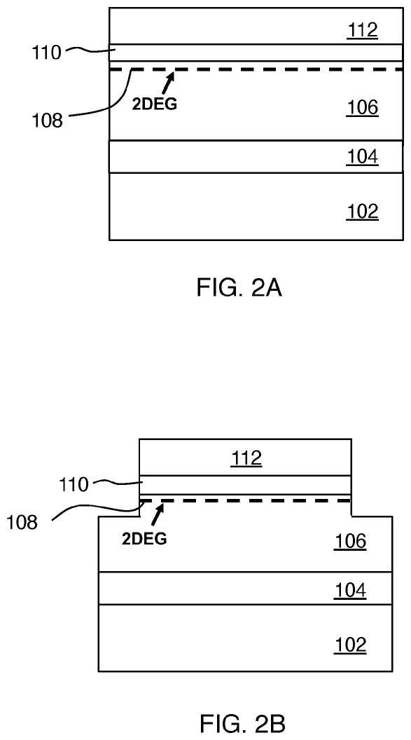

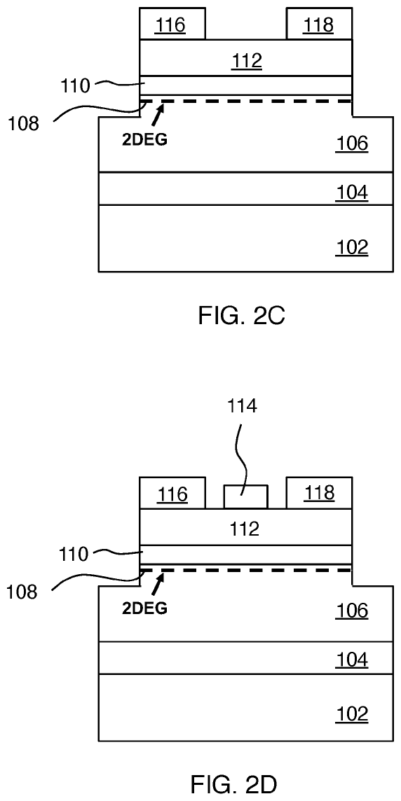

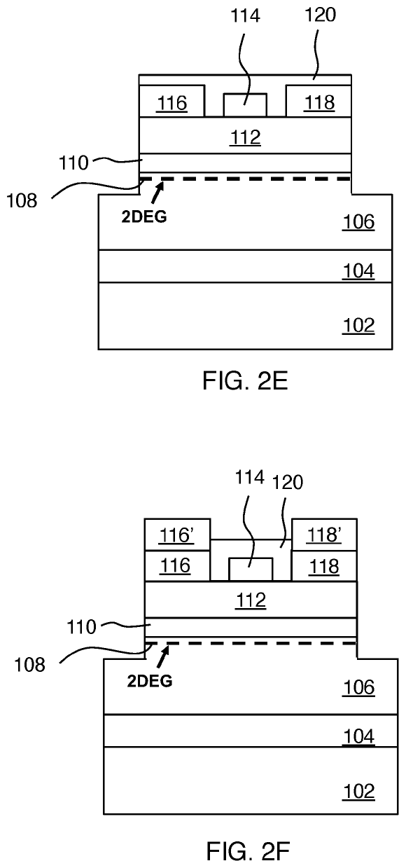

FIGS. 2A-E shows an exemplary fabrication sequence. Practice of the invention is not limited to the specific substrate or nitride materials of the example of FIG. 1, so a more generic description of the device layers is used here. This fabrication sequence includes a 2D electron gas, which is also not required to practice the invention. Schottky contacts as described herein of iridium oxide as fabricated and protected with passivation are expected to be useful for making rectifying contact to any III-nitride device structure.

FIG. 2A shows the result of epitaxial growth of a typical stack of device layers. Here 102 is the substrate, 104 is the buffer, and 106 is the lowest device layer. As such, layer 106 is of a III-Nitride material, while the substrate 102 and buffer 104 can have any composition suitable for the growth of layer 106 (and thus need not be III-Nitride materials). In this example, device layer 106 optionally includes a 2D electron gas 108 (as in the example of FIG. 1) and optionally include further III-Nitride device layers 110 and 112 whose presence and purpose will depend on the specific device being fabricated. Practice of the invention does not depend critically on the type of III-Nitride device being made.

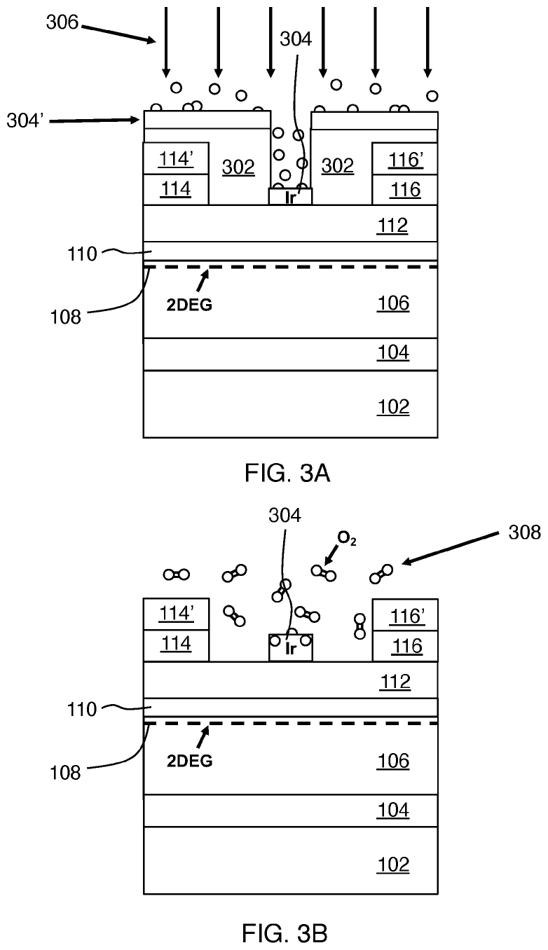

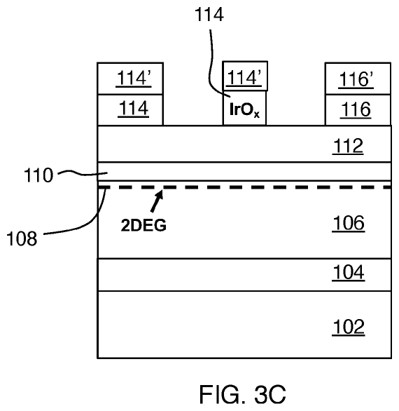

FIG. 2B shows the result of a mesa etch to define lateral device boundaries. FIG. 2C shows the result of an ohmic contact deposition and annealing step to form source 116 and drain 118. FIG. 2D shows the result of a Schottky contact deposition and annealing step to form gate 114. This process step is considered in greater detail below. FIG. 2E shows the result of depositing passivation structure 120. FIG. 2F shows the result of passivation etch back and deposition of bond pads 116′ and 118′ for source 116 and drain 118 respectively. For simplicity fabrication of bond pad 114′ of FIG. 1 is not shown on FIGS. 2A-F, but it is shown on FIG. 3C.

FIGS. 3A-C show the gate fabrication step of FIG. 2D in greater detail. FIG. 3A shows deposition of iridium structure 304 in a pattern defined by mask 302. Here 306 schematically shows the incident iridium, for example from an e-beam evaporator, and iridium 304′ is also deposited on mask 302 (but is removed when the mask is removed). Practice of the invention does not depend critically on how the iridium structure 304 is deposited or patterned. FIG. 3B shows the step of exposing iridium structure 304 to an oxygen ambient 308 at high temperatures (e.g., a temperature range from 700° C. to 1000° C.). This step is performed after removal of mask 302. The duration of this step is preferably in a range from 15 seconds to 5 minutes, with longer times generally corresponding to lower temperatures. FIG. 3C shows the result of depositing a gate contact pad 114′ on top of the iridium oxide structure 114 formed by the step of FIG. 3B.

### C) Passivation Considerations

It is important to note that passivation of high temperature devices is an unpredictable aspect of device technology. The net effect of any protection provided by passivation and any new device degradation or failure mechanisms introduced by adding passivation, especially at extreme temperatures, is notoriously difficult to predict. Thus an important aspect of this work is the experimental demonstration that passivation is a net benefit for these kinds of Schottky contacts in III-Nitride devices. For completeness, further considerations relating to passivation follow.

Degradation mechanisms are the physical, chemical, thermodynamic, mechanical or other processes that worsen device performance. Device “failure”, and the difference between partial or total failure, is subjective; the tolerance limits for semiconductor device reliability are determined by application. Common tolerance limits for commercial-off-the-shelf (COTS) semiconductor devices are within ±20% over the temperature range, which is usually −40° C. to +150° C. Some applications require higher reliability than others and will therefore require parameter tolerances to be kept within narrower limits. In this work, the term “failure” is only used to refer to total, permanent device failure (e.g. the device no longer conducts current on the same order of magnitude). Reliable operation of InAlN/GaN HEMTs at high temperature is frequently limited not by the heterostructure itself, but by premature failure of the contact metallization or passivation scheme. Reported high-temperature degradation mechanisms associated with the contacts include gate sinking, metal accumulation that leads to ball-up, gold diffusion, and electromigration.

An additional material is frequently coated onto the top of GaN HEMTs to “passivate” the device surface. The passivation layer has the advantage of shielding the GaN heterostructure from chemical reactions, contamination, and oxidation of the barrier layer. By isolating the heterostructure from its environmental conditions, the semiconducting properties of the device can be preserved. Passivation techniques can be particularly important in GaN devices to stabilize the donor-like states at the surface of the InAlN layer that are the origin of the electrons in the 2 DEG. Inert materials with high chemical corrosion such as silicon nitride (SiNx) and aluminum oxide (Al₂O₃) are frequently used to passivate the surface of GaN HEMTs.

Yet, passivation is not without its drawbacks for high temperature operation. While the InAlN/GaN HEMT system can be lattice matched to mitigate stress in the heterostructure, the addition of a passivation layer frequently induces stress in the system. Passivation materials are normally amorphous. The resulting passivation films are brittle and can be non-stochiometric, which can lead to a thermal stress profile. This can be a reliability issue for high temperature device applications. As the temperature of operation is increased, thermal mismatch between the passivation and substrate can lead to cracking in the passivation layer. E.g., there is a literature report of cracking in Si₃N₄-passivated InAlN/GaN-on-SiC HEMTs at 900° C. around the mesa edge, which interfered with the gate metallization.

### D) Circular Geometry

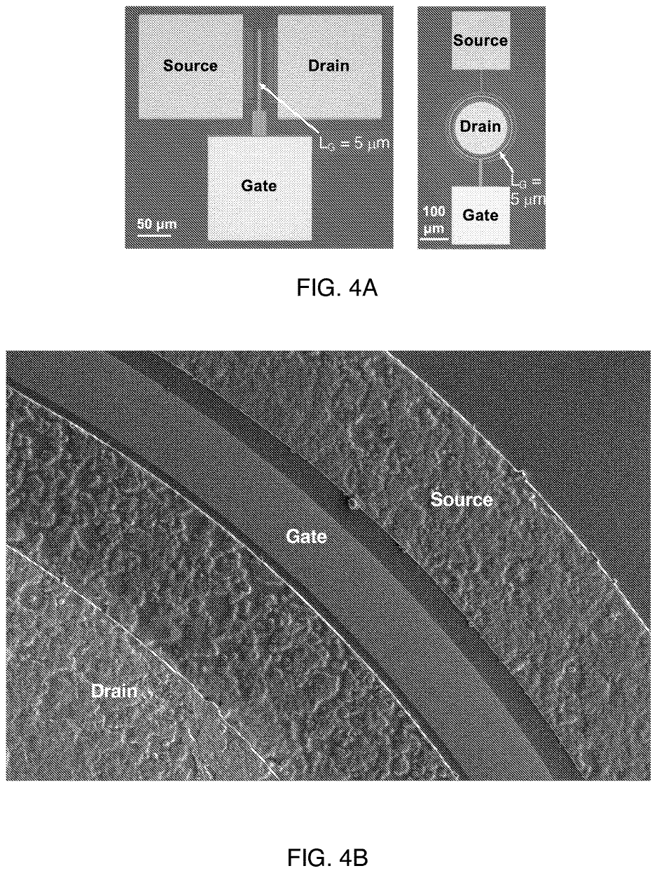

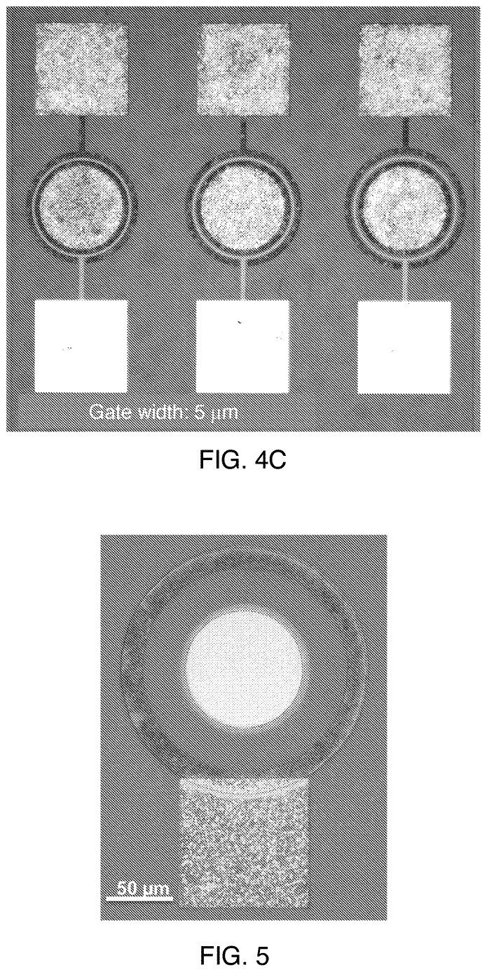

The conventional geometry of HEMTs is rectangular or linear (L-HEMT). FIG. 4A shows a typical L-HEMT layout on the left. The L-HEMT source, gate, and drain are parallel rectangles. An alternative device geometry is the annular or circular HEMT (C-HEMT), where the drain, gate, and source are concentric circles (FIG. 4A, on the right). C-HEMT devices fall into the category of enclosed layout transistors (ELTs). The C-HEMT layout offers several advantages over the standard L-HEMT layout. L-HEMT devices suffer from electric field crowding at the sharp gate edge, which causes local device breakdown. C-HEMTs generally do not have this issue because the electric field evenly distributes around the circular gate. The is a literature report of 50% higher breakdown voltages in GaN C-HEMTs compared to L-HEMTs. Individual L-HEMTs generally offer smaller footprints than C-HEMTs, which is desirable for achieving large packing densities. However, another literature report demonstrated size savings of 18.6% in C-HEMTs compared to L-HEMTs by using an overlapping gate geometry. Additionally, higher effective (W/L) and faster transient switching was achieved in C-HEMT devices with minimized source and drain junction areas. This implies the C-HEMT geometry is favorable for high frequency operation.

Another advantage of the C-HEMT transistor for extreme environment space applications is that ELTs are well-known to provide improved radiation hardness due to effective prevention of leakage currents. Radiation hardening FETs against total-ionizing dose effects can be achieved by using the enclosed gate format, which eliminates the edges known to cause leakage paths in NMOS transistors.

Furthermore, the C-HEMT geometry eliminates issues with the gate-mesa sidewall overlap region in L-HEMTs. Plasma dry etching is commonly used to achieve device isolation for L-HEMTs. However, this microfabrication technique introduces reliability issues. First, a high density of traps is generated at the mesa sidewall due to plasma-induced damage. Second, the gate contact is in direct contact with the 2 DEG in the region where it overlaps the mesa sidewall, forming a parasitic leakage path. Additionally, this area is prone to gate sinking of the gate metal atoms into the 2 DEG channel due to the direct contact. In the L-HEMT geometry, there are two gate-mesa sidewall overlap regions at each end of the mesa, which are necessary for complete channel modulation.

C-HEMT geometry can reduce or eliminate these issues because device isolation is inherent to the concentric nature of the contacts. This means that mesa isolation plasma etching is not necessary in C-HEMT microfabrication. If mesa etching is present, there is only one region of mesa-sidewall overlap instead of two regions like in the L_HEMT. Furthermore, because the drain pad is contained within the circular gate and source contacts, the parasitic off-state leakage path from the drain pad to the gate pad is not present in C-HEMT devices.

The C-HEMTs were operated in internal drain bias configuration mode (IDBC). In this configuration, the inner concentric circle is biased as the drain and the outermost concentric circle is the source. IDBC has been shown to increase the drain saturation current compared to external drain bias configuration (EDBC) due to differences in the longitudinal electric field densities.

FIGS. 4B-C are further images of fabricated C-HEMT devices. In particular, FIG. 4B is a scanning electron microscope (SEM) image of a passivated IrOₓ-gated circular InAlN/GAN HEMT after 600° C. testing. FIG. 4C is an image of microfabricated Al₂O₃ passivated IrOₓ-gated circular InAlN/GaN HEMTs of various channel lengths.

### E) Further Characterization

The high temperature performance of these Schottky contacts was verified by detailed device characterization of the Schottky diode included in the structure of FIG. 1. In other words, this HEMT device structure was used to characterize the Schottky diode formed at the interface between IrOₓ gate 114 and InAlN layer 112. FIG. 5 is an SEM image of such a device. Further fabrication details for this work follow.

Schottky diodes are fabricated on a lattice-matched In_{0.18}Al_{0.82}N/AlN/GaN-on-Si wafer grown via metal organic chemical vapor deposition (MOCVD). The InAlN barrier layer is 10 nm thick, the AlN spacer is 0.8 nm thick, the GaN barrier layer is 1 μm thick, the buffer layer is 300 nm thick, and the high resistivity Si substrate is 625 μm thick (supplier: NTT Corporation). The circular device active region was defined by a BCl₃/Cl₂ inductively coupled reactive ion mesa etch. Ti/Al/Mo/Au (15/60/35/50 nm) metals were evaporated, lifted off, and annealed in N₂ at 850° C. for 30 s to form the ring-shaped Ohmic contact around the perimeter. Next, a 15-nm-thick film of Ir was evaporated, lifted off, and intentionally oxidized at 800° C. for 1 min in O₂ to form a concentric, circular Schottky gate contact. This processing has been reported by others to result in 25-30 nm IrO₂ throughout the as-deposited Ir thin film when utilized on AlGaN/GaN. Here, we refer to the gate electrode stack as IrOₓ (i.e., the x denotes that the stoichiometry is not precisely known (or relevant) ) because the exact oxide composition of the intentionally oxidized iridium stack was not independently verified. The transformation of the Ir contact into IrO₂ on AlGaN films proceeds from the top down towards the semiconductor interface during the oxidation process. At the temperature of oxidation (800° C.), oxygen has a long diffusion length in Ir, which is highly reactive. The intentional oxidation at high temperature far above the intended temperature of operation is believed to be a contributing factor to the thermal stability of the Schottky contacts investigated in this work.

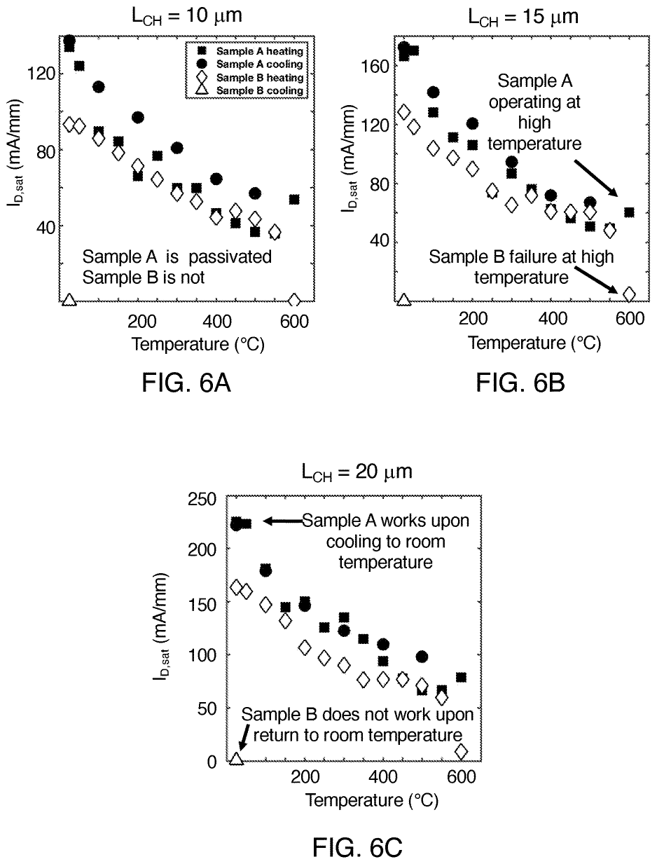

FIGS. 6A-C show temperature cycling results. Here passivation was seen to be essential in order for devices of three different channel lengths to survive a temperature excursion to 600° C.

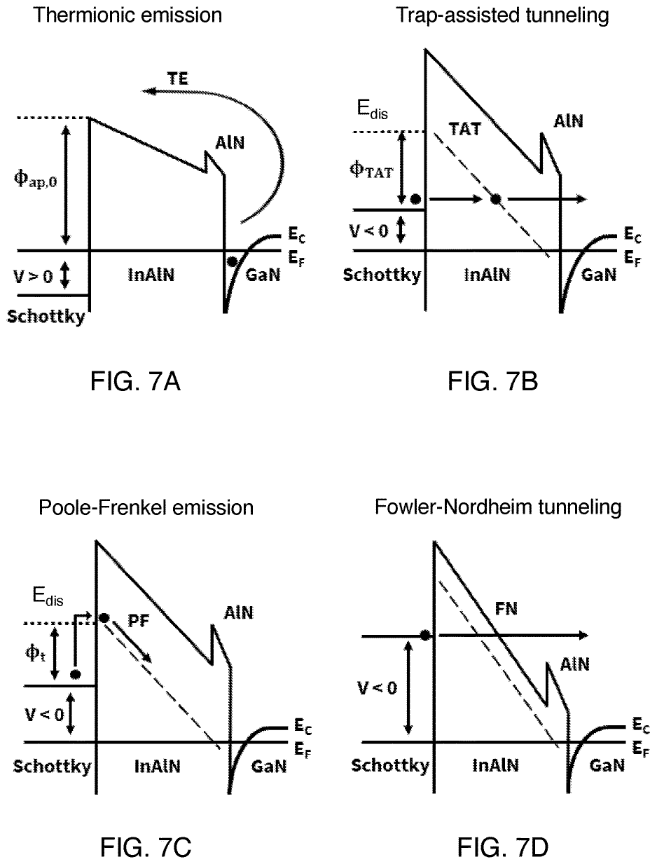

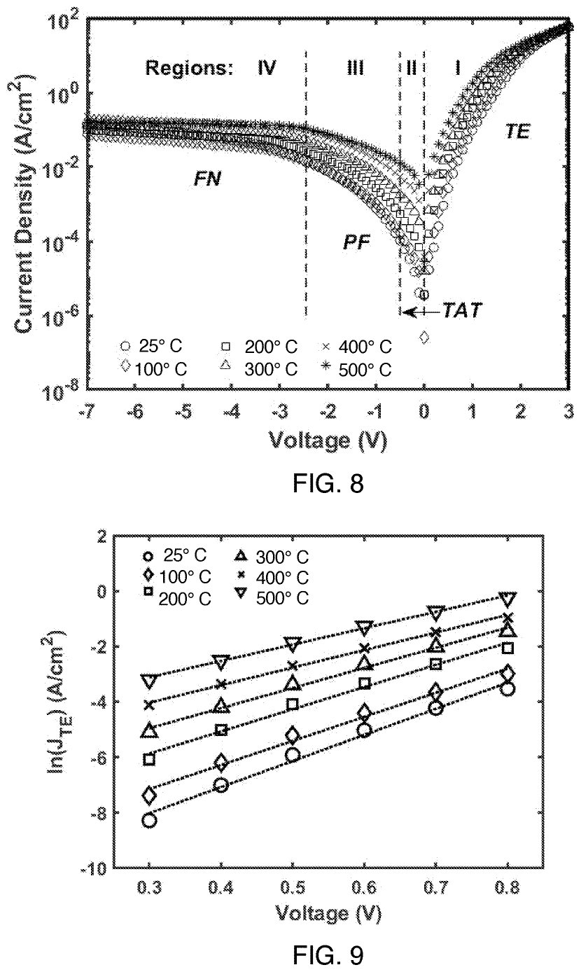

In addition to the survival testing shown on FIGS. 6A-C, detailed characterization of this Schottky contact was conducted, including consideration of various current flow mechanisms such as thermionic emission (FIG. 7A), trap-assisted tunneling (FIG. 7B), Poole-Frenkel emission (FIG. 7C), and Fowler Nordheim tunneling (FIG. 7D). Both forward biased and reverse biased operation were characterized in detail. FIG. 8 shows a representative result, where a passivated IrOₓ Schottky contact device shows rectifying behavior over an extremely wide temperature range. FIG. 9 is another example of this characterization work, showing data over a wide temperature range relating to thermionic emission current. Far more characterization work than shown on FIGS. 8 and 9 has been performed on these devices. The bottom line conclusion of this characterization work is that passivated IrOx Schottky contact devices do more than just survive at these elevated temperature—they operate properly at these elevated temperatures. A summary of this work follows.

InAlN/GaN Schottky diodes with novel conductive iridium oxide (IrOₓ) anode contacts were fabricated. The Schottky barrier height inhomogeneity was investigated and both the mean barrier heights and standard deviations were reported at moderate and high temperatures up to 500° C. (≈300 K to 773 K) in air. The IrOₓ anode exhibits a high Schottky barrier height of 1.55-2.33 eV on InAlN. The double Gaussian distribution methodology used is supported by the analysis of Richardson plot parameters, which gives Richardson constants, A*, of 75.62 Acm⁻²K⁻² and 61.87 Acm⁻²K⁻². The high barrier height reported in this work demonstrates that intentionally oxidized IrOₓ thin films have potential to be utilized as a thermally robust Schottky gate electrode to InAlN/GaN heterostructure devices like the HEMT, and as an anode to other epitaxial thin film stacks with AlN-based layers.

The reverse leakage current transport mechanisms in IrOₓ contacts on the InAlN/GaN heterostructure were also investigated. Temperature-dependent current-voltage characteristics were obtained on microfabricated Schottky diodes. In reverse bias, three current transport mechanisms contributing to reverse leakage current were identified: trap-assisted tunneling at low reverse bias, Poole-Frenkel emission at medium reverse bias, and Fowler-Nordheim tunneling at high reverse bias. The temperature-dependency of these mechanisms has been studied up to very high temperatures of 500° C. (˜773 K) previously unreported for InAlN devices. The parameters for each mechanism were used to create a current versus electric field model, which closely followed the experimental data at 25° C. and 500° C. These results provide valuable insight into the mechanisms contributing to undesirable reverse leakage currents in InAlN/GaN HEMTs operating at high temperature, and furthermore indicate IrOₓ Schottky gates to InAlN/GaN HEMTs could be a viable solution for very hot extreme environment applications.

1. A method of making a Schottky contact in a III-nitride device structure, the method comprising:
depositing an iridium structure on a III-nitride device structure;
oxidizing the iridium structure to convert it to an iridium oxide structure at a oxidizing temperature of 700° C. or more, thereby forming a Schottky contact; and
depositing a passivation structure on the iridium oxide structure.

2. The method of claim 1, wherein the passivation structure includes one or more materials selected from the group consisting of: aluminum oxide, silicon dioxide, silicon nitride, and silicon oxynitride.

3. The method of claim 1, wherein the III-Nitride device structure is an InAlN structure on a GaN substrate.

4. The method of claim 1, wherein the Schottky contact can operate at temperatures up to 500° C.

5. The method of claim 1, wherein the iridium oxide structure is electrically conductive.

6. The method of claim 5, wherein the iridium oxide structure acts as a gate contact to the III-Nitride device structure.

7. The method of claim 6, wherein the III-Nitride device structure is a gated 2D electron gas device.

8. The method of claim 6, wherein the III-Nitride device structure is a transistor structure.

9. The method of claim 8, wherein the III-Nitride device structure is a high electron mobility transistor.

10. The method of claim 8, wherein the transistor structure has a circular geometry having concentric source, gate and drain terminals.

11. The method of claim 1, wherein the oxidizing temperature is 1000° C. or less.
